(19) United States
(12) Patent Application Publication
(10) Pub. No.: US 2025/0294875 A1
(43) Pub. Date: Sep. 18, 2025

(54) BACKSIDE SELF-ALIGNED DIFFUSION BREAKS

(71) Applicant: International Business Machines Corporation, Armonk, NY (US)

(72) Inventors: Manasa MEDIKONDA, ALBANY, NY (US); Tao Li, Slingerlands, NY (US); Ruilong Xie, Niskayuna, NY (US); Shay Reboh, Guilderland, NY (US)

(21) Appl. No.: 18/607,634

(22) Filed: Mar. 18, 2024

(51) Int. Cl. H01L 27/12

(52) U.S. Cl. CPC H10D 86/0214; H10D 86/441; H10D 86/60

(57) ABSTRACT

Embodiments disclosed herein include a semiconductor structure. The semiconductor structure may include a back-end-of-line (BEOL) on a first side of a front-end-of-line (FEOL), a backside power delivery network (BSPDN) on a second side of the FEOL, a backside single diffusion break (BSDB) tapered from the BSPDN to the BEOL, and a backside double diffusion break (BDDB) tapered from the BSPDN to the BEOL.

### BACKGROUND

The present invention relates generally to the field of semiconductor device manufacturing, and more particularly to locations and orientation of diffusion breaks.

Single diffusion breaks (SDBs) and double diffusion breaks (DDBs) are techniques to isolate neighboring devices in a semiconductor structure. SDBs use a shallow trench isolation (STI) with a width of one gate length, while DDBs use a fin tuck under dummy poly with a width of one poly pitch. SDBs and DDBs have different effects on the performance and leakage of the devices, depending on the layout context and the stress induced by the source/drain (S/D) epitaxy. SDBs can reduce the die area, but they also cause more variability and layout-dependent effects (LDEs) due to the heavy facet of S/D epi at the edge of STI. DDBs can increase the speed and immunity of the devices, but they also require more area and leakage power, and they can relax the stress due to the free space at the fin-cut edge. Therefore, choosing between SDBs and DDBs depends on the trade-off between area, speed, leakage, and variability in the semiconductor design.

### SUMMARY

Aspects of an embodiment of the present invention include a semiconductor structure. The semiconductor structure may include a back-end-of-line (BEOL) on a first side of a front-end-of-line (FEOL), a backside power delivery network (BSPDN) on a second side of the FEOL, a backside single diffusion break (BSDB) tapered from the BSPDN to the BEOL, and a backside double diffusion break (BDDB) tapered from the BSPDN to the BEOL.

Aspects of an embodiment of the present invention encompass a method of fabricating a semiconductor structure. The method may include forming a back-end-of-line (BEOL) on a first side of a front-end-of-line (FEOL), forming a backside single diffusion break (BSDB) tapered toward the BEOL, forming a backside double diffusion break (BDDB) tapered toward the BEOL, and forming a backside power delivery network (BSPDN) on a second side of the FEOL.

Aspects of an embodiment of the present invention include a semiconductor structure. The semiconductor structure may include a backside single diffusion break (BSDB) located on a first row of a front-end-of-line (FEOL) layer of the semiconductor structure and a backside double diffusion break (BDDB) located on a second row of the FEOL layer, wherein the second row is directly adjacent to the first row.

### BRIEF DESCRIPTION OF THE DRAWINGS

FIG. 1 depicts a schematic top view of a semiconductor structure at a stage of fabrication, in accordance with one embodiment of the present invention.

FIGS. 2A-2D depict cross-sectional side views of the semiconductor structure of FIG. 1 at a fabrication stage of the processing method, in accordance with one embodiment of the present invention.

FIGS. 3A-3D depict cross-sectional side views of the semiconductor structure of FIG. 1 at a fabrication stage of the processing method, in accordance with one embodiment of the present invention.

FIGS. 4A-4D depict cross-sectional side views of the semiconductor structure of FIG. 1 at a fabrication stage of the processing method, in accordance with one embodiment of the present invention.

FIGS. 5A-5D depict cross-sectional side views of the semiconductor structure of FIG. 1 at a fabrication stage of the processing method, in accordance with one embodiment of the present invention.

FIGS. 6A-6D depict cross-sectional side views of the semiconductor structure of FIG. 1 at a fabrication stage of the processing method, in accordance with one embodiment of the present invention.

FIGS. 7A-7D depict cross-sectional side views of the semiconductor structure of FIG. 1 at a fabrication stage of the processing method, in accordance with one embodiment of the present invention.

FIGS. 8A-8D depict cross-sectional side views of the semiconductor structure of FIG. 1 at a fabrication stage of the processing method, in accordance with one embodiment of the present invention.

FIGS. 9A-9D depict cross-sectional side views of the semiconductor structure of FIG. 1 at a fabrication stage of the processing method, in accordance with one embodiment of the present invention.

FIGS. 10A-10D depict cross-sectional side views of the semiconductor structure of FIG. 1 at a fabrication stage of the processing method, in accordance with one embodiment of the present invention.

FIGS. 11A-11D depict cross-sectional side views of a semiconductor structure in a similar orientation of rows and columns to the depiction in FIG. 1, in accordance with one embodiment of the present invention.

### DETAILED DESCRIPTION

In the following detailed description, reference is made to the accompanying drawings, which show specific examples of embodiments of the invention. These embodiments are described in sufficient detail to enable those skilled in the art to practice them, and it is to be understood that other embodiments may be utilized, and that structural, logical, and electrical changes may be made without departing from the described embodiments. The following detailed description is, therefore, not to be taken in a limiting sense, and the included embodiments are defined by the appended claims.

In the following description, numerous specific details are set forth, such as particular structures, components, materials, dimensions, processing steps and techniques, in order to provide an understanding of the various embodiments of the present application. However, it will be appreciated by one of ordinary skill in the art that the various embodiments of the present application may be practiced without these specific details. In other instances, well-known structures or processing steps have not been described in detail in order to avoid obscuring the present application.

References in the specification to “one embodiment,” “an embodiment,” “certain embodiments,” etc., indicate that the embodiment described may include a particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to affect such feature, structure, or characteristic in connection with other embodiments whether or not explicitly described.

For purposes of the description hereinafter, the terms “upper,” “right,” “left,” “vertical,” “horizontal,” “top,” “bottom,” and derivatives thereof shall relate to the disclosed structures and methods, as oriented in the drawing Figures. The terms “above,” “below,” “positioned on,” or “positioned atop” mean that a first element, such as a first structure, is present on a second element, such as a second structure, wherein intervening elements, such as an interface structure may be present between the first element and the second element. The term “direct contact” means that a first element, such as a first structure, and a second element, such as a second structure, are connected without any intermediary conducting, insulating or semiconductor layers at the interface of the two elements.

It will be understood that when an element as a layer, region or substrate is referred to as being “on” or “over” another element, it can be directly on the other element or intervening elements may also be present. In contrast, when an element is referred to as being “directly adjacent,” “directly on,” or “directly over” another element, there are no intervening elements present. It will also be understood that when an element is referred to as being “beneath” or “under” another element, it can be directly below or under the other element, or intervening elements may be present. Additionally, when an element is referred to as being “directly below” or “directly above” another element, intervening elements may be present, but the elements overlap at least partially relative to a vertical axis perpendicular to a major surface. With regard to the fabrication of transistors and integrated circuits, major surface refers to that surface of the semiconductor layer in and about which a plurality of transistors are fabricated, e.g., in a planar process. As used herein, the term “vertical” means substantially orthogonal with respect to the major surface and “horizontal” means substantially parallel to the major surface. Typically, the major surface is along a plane of a monocrystalline silicon layer on which transistor devices are fabricated. Each reference number may refer to an item individually or collectively as a group. For example, a contact 202 may refer to a single contact 202 or multiple contacts 202.

Although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of example embodiments. As used herein, the term “and/or” includes any and all combinations of one or more of the associated listed items.

The terms “epitaxial growth and/or deposition” and “epitaxially formed and/or grown” mean the growth of a semiconductor material (crystalline material) on a deposition surface of another semiconductor material (crystalline material), in which the semiconductor material being grown (crystalline overlayer) has substantially the same crystalline characteristics as the semiconductor material of the deposition surface (seed material). In an epitaxial deposition process, the chemical reactants provided by the source gases can be controlled and the system parameters can be set so that the depositing atoms arrive at the deposition surface of the semiconductor substrate with sufficient energy to move about on the surface such that the depositing atoms orient themselves to the crystal arrangement of the atoms of the deposition surface. An epitaxially grown semiconductor material can have substantially the same crystalline characteristics as the deposition surface on which the epitaxially grown material is formed. In some embodiments, epitaxial growth and/or deposition processes can be selective to forming on semiconductor surfaces, and may or may not deposit material on other exposed surfaces, such as silicon dioxide or silicon nitride surfaces.

Example embodiments are described herein with reference to cross-sectional illustrations that are schematic illustrations of idealized or simplified embodiments (and intermediate structures). As such, variations from the shapes of the illustrations as a result, for example, of manufacturing techniques and/or tolerances, may be expected. Thus, the regions illustrated in the figures are schematic in nature and their shapes do not necessarily illustrate the actual shape of a region of a device and do not limit the scope.

It is to be understood that other embodiments may be used, and structural or logical changes may be made, without departing from the spirit and scope defined by the claims. The description of the embodiments is not limiting. In particular, elements of the embodiments described hereinafter may be combined with elements of different embodiments.

In some embodiments, etching mask layer(s) may be provided, and the layers that are not protected thereby are removed. For example, as is understood in the art, a mask layer, sometimes referred to as a photomask, may be provided by forming a layer of photoresist material on another layer, exposing the photoresist material to a pattern of light, and developing the exposed photoresist material. An etching process, such as a reactive ion etch (RIE), may be used to form patterns (e.g., openings) by removing portions of another layer. After etching, the mask layer may be removed using a conventional plasma ashing or stripping process. Accordingly, the pattern of the mask layer facilitates the removal of another layer, such as an amorphous SiO2 layer and/or a conductive oxide diffusion barrier, for example, in areas where the mask layer has not been deposited.

For the sake of brevity, conventional techniques related to semiconductor structure and integrated circuit (IC) fabrication may or may not be described in detail herein. Moreover, the various tasks and process steps described herein can be incorporated into a more comprehensive procedure or process having additional steps or functionality not described in detail herein. In particular, various steps in the manufacture of semiconductor structures and semiconductor-based ICs are well known and so, in the interest of brevity, many conventional steps will only be mentioned briefly herein or will be omitted entirely without providing the well-known process details.

Improvements in the design of integrated circuits (IC) have enabled feature sizes for transistors in a device layer to enter into deep submicron and nanometer regime. Embodiments herein recognize benefits from separating the power delivery components from the signal wires. A backside power delivery network (BSPDN), for example, can greatly improve the routability for field-effect transistors (FETs). Improving routability means the design of the IC provides easier connection between source/drains (S/Ds), gates, etc. and the other components of the IC. The embodiments herein also recognize that the decrease in feature size can mean a greater potential for defect even with very slight misalignment in a lithographic mask.

The embodiments described herein, therefore, are fabricated with self-aligned isolation structure including double diffusion breaks and single diffusion breaks fabricated on the same wafer. Advantages of having a single diffusion break and a double diffusion break on the same wafer are flexibility and control over the electrical characteristics of each of the devices. A single diffusion break creates a junction between two regions of different doping levels, while a double diffusion break creates two junctions in series. By varying the width and depth of the breaks, as well as the doping concentrations, one can achieve different levels of breakdown voltage, leakage current, capacitance, and resistance. This can be useful for optimizing the performance of different types of devices, such as diodes, transistors, and sensors, on the same wafer.

Therefore, embodiments of the current invention may include semiconductor structures having structures that provide the technical benefit of isolating semiconductor components with diffusion breaks that can be fabricated from a backside with self-aligning processes that reduce the likelihood of defects. Such embodiments may be fabricated with a back-end-of-line (BEOL) on a first side of a front-end-of-line (FEOL), a backside power delivery network (BSPDN) on a second side of the FEOL, a backside single diffusion break (BSDB) tapered from the BSPDN to the BEOL, and a backside double diffusion break (BDDB) tapered from the BSPDN to the BEOL.

In certain embodiments, the BSDB is located on a first row and the BDDB is located on second row adjacent to the first device line, highlighting the technical advantage of being able to fabricate both types of diffusion breaks on a single wafer, and in close proximity. That is, the components and fabrication methods disclosed herein enable an improved ability to fabricate the diffusion breaks close together without defects. In such embodiments, a first row may include an NFET semiconductor and the second row may include a PFET semiconductor with the advantage of close fabrication not being affected.

Certain embodiments of the present invention may include a first source/drain (S/D) directly adjacent to the BSDB and a placeholder directly beneath the first S/D for the benefit of self-aligned fabrication such that the BSDB is formed without a backside interlayer dielectric. Certain of these embodiments may include a second S/D directly adjacent to the BSDB on an opposite side of the first S/D and a backside S/D contact electrically connected between the second S/D and the BSPDN providing the technical benefit of electrical communication between the S/Ds and both the BSPDN and the BEOL. The BSDB of these embodiment may be directly between the placeholder and the backside S/D contact further indicating the self-aligned aspects of the fabrication of these embodiments. These embodiments may further include a backside gate-and-S/D cut dielectric between the placeholder and the BDDB.

Certain embodiments of this invention may include methods of fabricating semiconductor structures that include forming a back-end-of-line (BEOL) on a first side of a front-end-of-line (FEOL), forming a backside single diffusion break (BSDB) tapered toward the BEOL, forming a backside double diffusion break (BDDB) tapered toward the BEOL, and forming a backside power delivery network (BSPDN) on a second side of the FEOL. These steps enable a single wafer to be fabricated with both a single diffusion break and a double diffusion break, and enable control over the electrical characteristics of each of the devices. A single diffusion break creates a junction between two regions of different doping levels, while a double diffusion break creates two junctions in series. By varying the width and depth of the breaks, as well as the doping concentrations, one can achieve different levels of breakdown voltage, leakage current, capacitance, and resistance. This can be useful for optimizing the performance of different types of devices, such as diodes, transistors, and sensors, on the same wafer.

Methods of the disclosed embodiments may include etching a BSDB cut that is self-aligned between a first placeholder and a second placeholder and replacing the first placeholder with a backside S/D contact. This provides the technical benefit of reducing defects caused by lithographic misalignment that can occur when patterning a hard mask.

Certain embodiments may include a backside single diffusion break (BSDB) located on a first row of a front-end-of-line (FEOL) layer of the semiconductor structure and a backside double diffusion break (BDDB) located on a second row of the FEOL layer. The second row may be directly adjacent to the first row highlighting the technical advantage of tailored isolation of semiconductor devices within a FEOL layer without any corresponding increase in fabrication defects.

The present invention and an example fabrication process will now be described in detail with reference to the Figures.

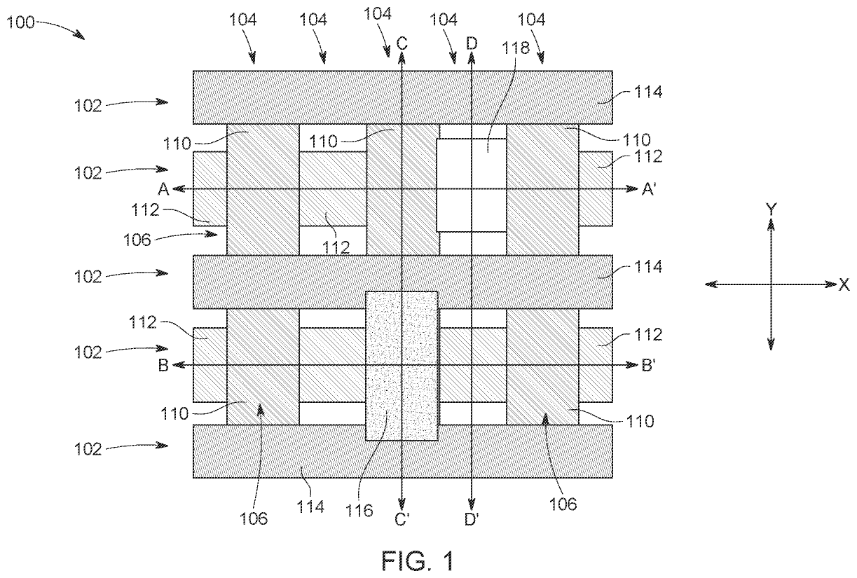

FIG. 1 depicts a schematic top view of a semiconductor structure 100 at a stage of fabrication, in accordance with one embodiment of the present invention. The semiconductor structure 100 is organized as rows 102 and columns 104 of field-effect transistor (FET) devices 106 fabricated in a device layer (i.e., front-end-of-line (FEOL) 108 in subsequent figures) of the semiconductor structure 100. The columns 104 include gates 110 that control channels between source/drains (S/Ds) 112 of the FET devices 106. The semiconductor structure 100 electrically connects the S/Ds 112 and gates 110 to a back-end-of-line (BEOL) interconnect network on a front side of the semiconductor structure 100 and/or to a backside power delivery network (BSPDN) on a backside of the semiconductor structure 100.

The semiconductor structure 100 also includes backside gate and S/D cut dielectrics (backside cut dielectrics) 114, a backside single diffusion break (BSDB) 116, and a backside double diffusion break (BDDB) 118. These structures isolate certain of the FET devices 106 as part of the circuit design for the semiconductor structure 100. The fabrication of these isolation structures (i.e., backside cut dielectrics 114, the BSDB 116, and the BDDB 118) can be a delicate operation, since small misalignment in a lithographic pattern can cause the gates 110 to short, or the S/Ds 112 to function with an increased resistance due to insufficient contact between the S/Ds 112 and the BEOL, or between the S/Ds 112 and the BSPDN. To alleviate the requirement for delicate alignment, the embodiments herein describe the BSDB 116 and the BDDB 118 as being fabricated from the backside using placeholder structures to self-align these components without relying wholly on lithographic masks and patterning. The semiconductor structure 100 includes other components (e.g., shallow trench isolation, interlayer dielectric, gate and S/D contacts) that are not illustrated in FIG. 1 so that the rows and columns of the semiconductor structure 100 may be more easily described. In the Figures below, cross-sectional views are shown that are shown from the lines indicated in FIG. 1. Two x-axis views are shown: A-A′ and B-B′; and two y-axis views: C-C′ and D-D′.

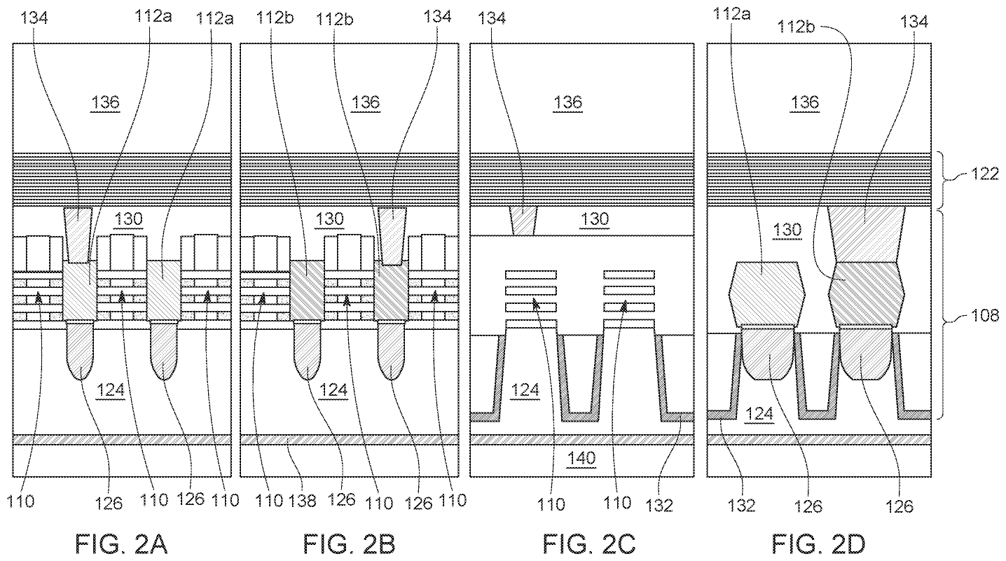

FIGS. 2A-2D depict cross-sectional side views of the semiconductor structure 100 of FIG. 1, with like reference numerals referring to like features at a fabrication stage of the processing method, in accordance with one embodiment of the present invention. FIG. 2A depicts the view along line A-A′; FIG. 2B depicts the view along line B-B′; FIG. 2C depicts the view along line C-C′; and FIG. 2D depicts the view along line D-D′. The semiconductor structure 100 includes the FEOL 108, as a layer below a BEOL 122. The FEOL 108 starts as a substrate 124, on which the gates 110 and the S/Ds 112 of the FET devices 106 are fabricated. The gates 110 are illustrated as being formed with nanosheet channels, spacers, and high-k metal gate material, but other gate structures and channel structures may function with the BSDB 116 and the BDDB 118 described herein. The S/Ds 112 are fabricated using epitaxial growth, and include: PFET S/Ds 112a formed, for example, from silicon germanium (SiGE) doped with boron; and NFET S/Ds 112b formed, for example, from silicon doped with phosphorus.

The semiconductor structure 100 (i.e., the FEOL 108) also includes bottom placeholders 126 that are formed to accommodate power connection from the back side. These placeholders 126 facilitate the BSDB 116 and the BDDB 118 as explained below. In short, the bottom placeholders 126 guide an etching process to cleanly remove parts of the semiconductor structure 100 without affecting other parts. As used herein, the term “cleanly” in reference to a material removal process (e.g., etching) denotes that, with an appropriate etchant choice, the material removal rate (i.e., etch rate) for the targeted material is greater than the removal rate for at least another material exposed to the material removal process. The semiconductor structure 100 may also include shallow trench isolation (STI) 128, interlayer dielectric (ILD) 130, and a bottom liner 132. These structures protect and separate the FET devices 106.

The semiconductor structure 100 also includes contacts 134 that electrically connect the gates 110 and the S/Ds 112 to the BEOL 122 (none of the illustrated components are necessarily drawn to scale). The BEOL 122 includes metal layers that interconnect the FET devices 106 over the entire wafer, and enable control of each individual FET device 106 during operation. The BEOL 122 connects the FET devices 106 to external power and communication sources, and includes many (e.g., dozens) of layers of wires, vias, and connects. The BEOL 122 layers are formed by first depositing insulating materials (typically silicon dioxide or low-k dielectrics) on top of the previous layer, then using lithography and etching techniques to define patterns for metal interconnects and vias in this insulating layer. Subsequently, metal layers (commonly aluminum or copper) are deposited, and further lithography and etching steps are employed to shape these layers into interconnects and vias. This process is repeated to build multiple layers of insulating materials, metal interconnects, and vias as needed for the specific semiconductor technology and device, ultimately finishing with a top insulating layer and a carrier wafer 136 that serves to protect the metal interconnects and complete the BEOL 122.

Once the BEOL 122 is complete, a carrier wafer 136 is bonded to the top side, so that the entire structure can be flipped, and fabrication processes can be completed on the bottom side of the FEOL 108. The semiconductor structure 100 may also include an etch stop layer 138 and a structural substrate 140, the function and utility of which will be explained in detail below.

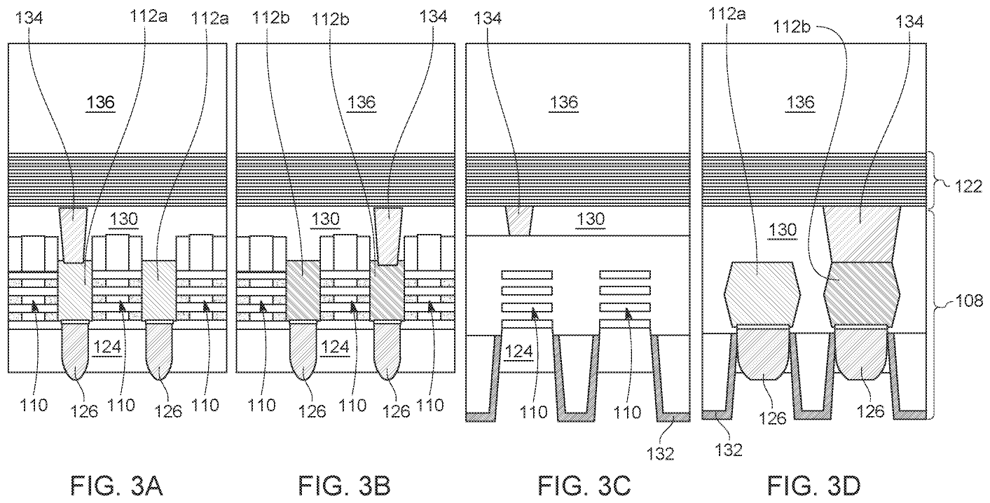

FIGS. 3A-3D depict cross-sectional side views of the semiconductor structure 100 of FIG. 1, with like reference numerals referring to like features at a fabrication stage of the processing method, in accordance with one embodiment of the present invention. The cross-sectional views are the same as the views above. That is, FIG. 3A depicts the view along line A-A′; FIG. 3B depicts the view along line B-B′; FIG. 3C depicts the view along line C-C′; and FIG. 3D depicts the view along line D-D′. The cross-sectional views in subsequent figures will also be along the same lines, and will not be individually labeled so as not to unnecessarily multiply this description.

The semiconductor structure 100 shows the removal of the backside of the FEOL 108. The semiconductor structure 100 is often flipped over, with support provided by the carrier wafer 136 on the frontside of the BEOL 122. The backside of the FEOL 108 may be removed in steps, with the structural substrate 140 being removed first through a rough etch process that is done with simultaneous monitoring of the etch stop layer 138. When the rough etch process contacts the etch stop layer 138, the rough etch stops. Monitoring the etch stop layer 138 saves the FEOL 108 from damage since using the rough etch process with alternative stopping mechanisms (e.g., timing) could potentially damage the components if an estimated etch rate is even slightly inaccurate. The etch stop layer 138 and enough of the substrate 124 to reveal the bottom placeholders 126 are removed with selective etch processes that are finer than the rough etch process. These finer processes do not affect the bottom liner 132 or the bottom placeholders 126.

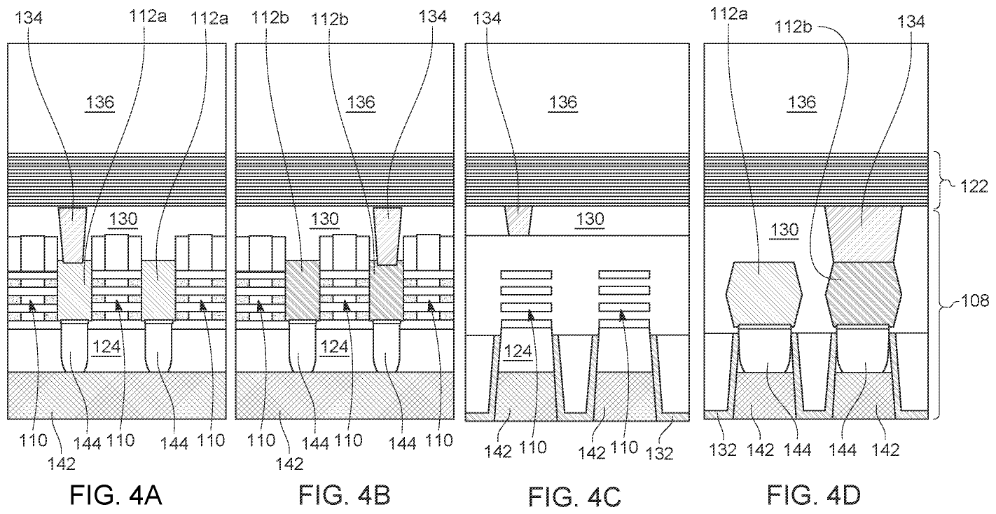

FIGS. 4A-4D depict cross-sectional side views of the semiconductor structure 100 of FIG. 1, with like reference numerals referring to like features at a fabrication stage of the processing method, in accordance with one embodiment of the present invention. The semiconductor structure 100 includes a cap dielectric deposition 142. The cap dielectric deposition 142 may be formed of materials like silicon carbide, etc which reacts to certain etchants in a different manner from the reactions of the bottom liner 132 and the STI 128, which enables clean etching of the cap dielectric deposition 142 from the bottom liner 132 and the STI 128, or vice versa. Certain embodiments of the semiconductor structure 100 may include replacement placeholders 144 that have replaced the initial bottom placeholders 126. This may be done due to the difficulty of forming a dielectric below the channel sheets of the gates 110. That is, growing a semiconducting material from the front side is easier, and attempts to deposit a dielectric material can result in disadvantages to the semiconductor structure 100 during etch processes. The semiconductor material of the bottom placeholders 126 is then replaced with a dielectric material of the replacement placeholders, which acts as a self-aligning hardmask for the BSDB 116 (as shown in detail below).

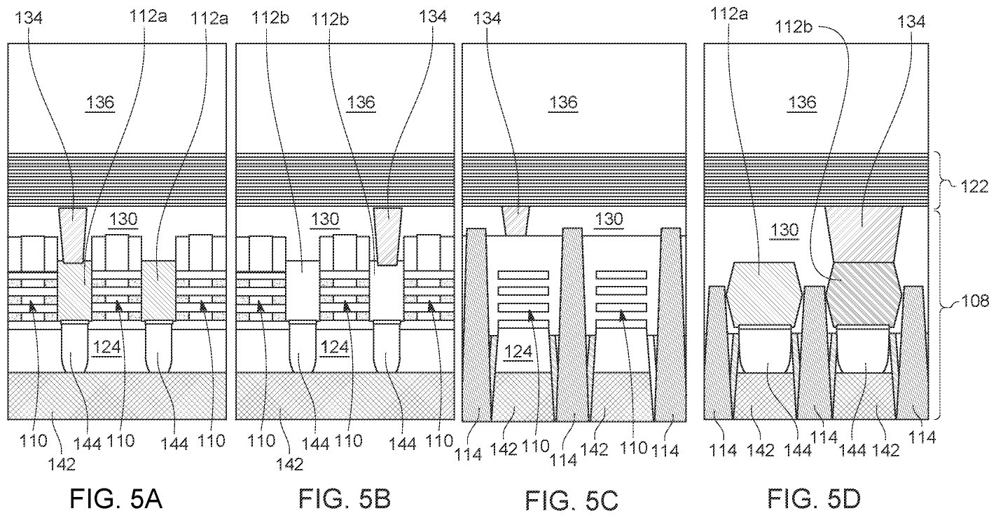

FIGS. 5A-5D depict cross-sectional side views of the semiconductor structure 100 of FIG. 1, with like reference numerals referring to like features at a fabrication stage of the processing method, in accordance with one embodiment of the present invention. The semiconductor structure 100 includes backside cut dielectrics 114 along the x-axis (see FIG. 1). These are formed by backside cut etches using a etch process that is selective to the bottom liner 132, the STI 128, the ILD 130, and the gates 110 (specifically the high-K metal gate material), but not selective to the silicon carbide of the cap dielectric deposition 142. The backside cut etches are then filled to form the backside cut dielectrics 114. The filling material is generally a dielectric material, such as silicon nitride (SiN), that will be cleanly etched selectively from the cap dielectric deposition 142. Using an etch process that does not affect the cap dielectric deposition 142 enables the backside cut dielectrics 114 to be self-aligned, meaning that the backside cut dielectrics 114 will be formed between the S/Ds 112 and between the gates 110 without needing lithographic masking. Self-aligned backside cut dielectrics 114 thus reduce or eliminate the chance of defects due to misalignment of components. The semiconductor structure 100 may be chemically-mechanically planarized (CMP) after the formation of the backside cut dielectrics 114.

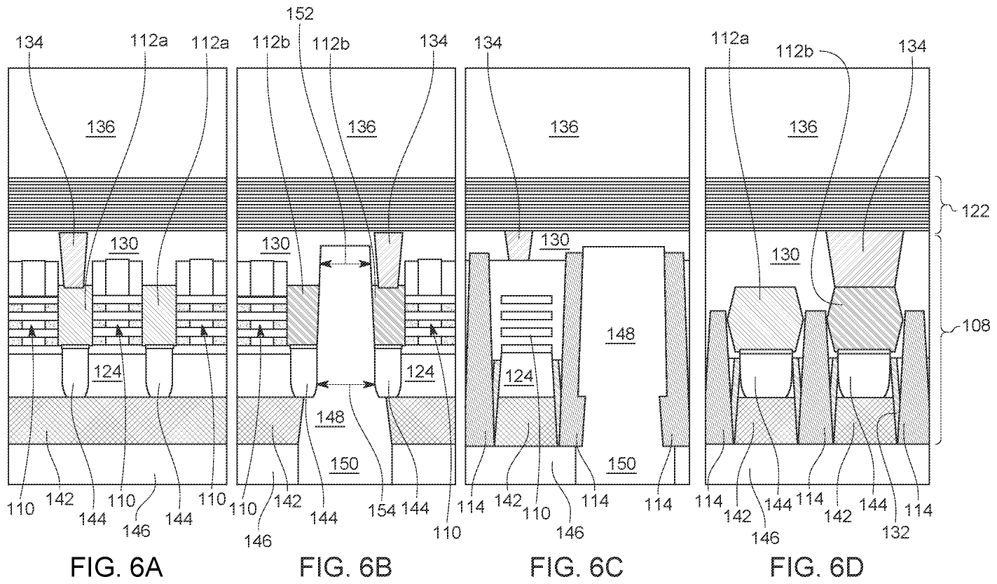

FIGS. 6A-6D depict cross-sectional side views of the semiconductor structure 100 of FIG. 1, with like reference numerals referring to like features at a fabrication stage of the processing method, in accordance with one embodiment of the present invention. The semiconductor structure 100 includes an organic planarization layer (OPL) 146 that acts as a hardmask for etching a BSDB cut 148. The OPL 146 may be patterned lithographically with an opening 150 before the BSDB cut 148 is etched into the semiconductor structure 100. The process for etching the BSDB cut 148 does not affect the backside cut dielectrics 114 or the replacement placeholders 144, however, so the BSDB cut 148 will be self-aligned between S/Ds 112 (in the illustrated embodiment the BSDB cut 148 is formed between NFET S/Ds 112b) and directly over, and etching away, of a channel region of a gate 110. This self-alignment will occur even if the lithography of the opening 150 is slightly inaccurate due to patterning misalignment. Furthermore, due to the direction of the etch process (i.e., from the backside) the taper of the BSDB cut 148 will be toward the BEOL 122. That is, a first critical dimension 152 of the BSDB cut 148 will be smaller in the portion close to the BEOL 122 and larger in the portion away from the BEOL 122 (which will eventually be closer to the BSPDN formed in the location described below).

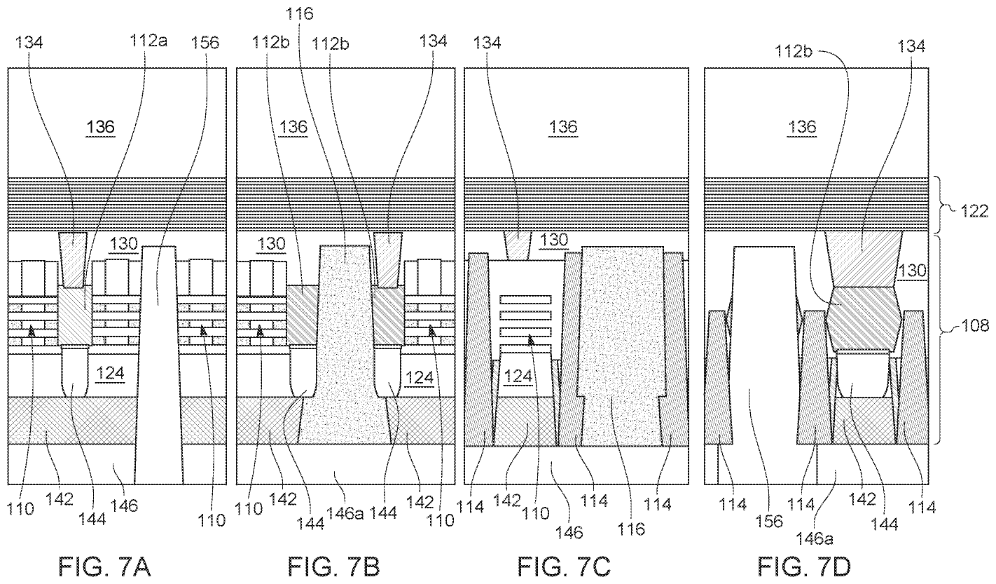

FIGS. 7A-7D depict cross-sectional side views of the semiconductor structure 100 of FIG. 1, with like reference numerals referring to like features at a fabrication stage of the processing method, in accordance with one embodiment of the present invention. The semiconductor structure 100 includes the BSDB 116 filled with dielectric material and a BDDB cut 156 etched through one of the PFET S/Ds 112a. The BDDB cut 156 is etched through a second application of OPL 146a, with the first OPL 146 being ashed before filling the BSDB 116. The second OPL 146a has a second opening 150a, but the BDDB cut 156 is also made with a selective etch process that enables self-aligned etching due to the backside cut dielectrics 114. The BDDB cut 156 is also tapered toward the BEOL 122.

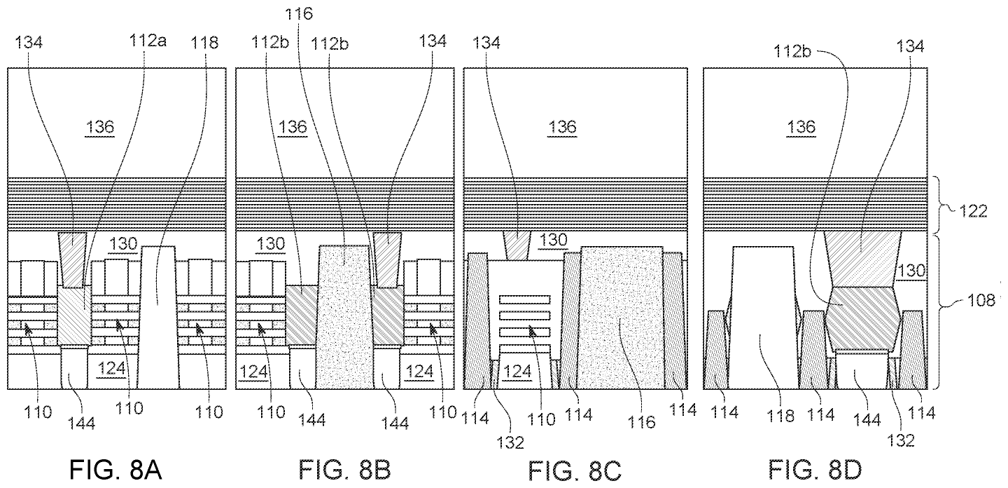

FIGS. 8A-8D depict cross-sectional side views of the semiconductor structure 100 of FIG. 1, with like reference numerals referring to like features at a fabrication stage of the processing method, in accordance with one embodiment of the present invention. The semiconductor structure 100 includes the BDDB 118 filled into the BDDB cut 156, and the backside of the semiconductor structure 100 is also uniformly reduced to remove the cap dielectric deposition 142 and reveal the substrate 124.

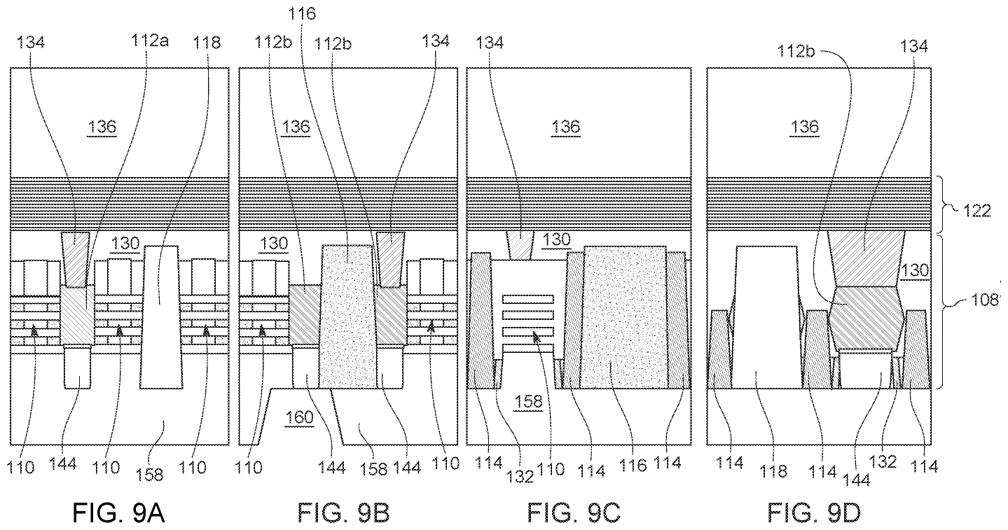

FIGS. 9A-9D depict cross-sectional side views of the semiconductor structure 100 of FIG. 1, with like reference numerals referring to like features at a fabrication stage of the processing method, in accordance with one embodiment of the present invention. The semiconductor structure 100 includes a backside interlayer dielectric (BILD) 158 replacing the substrate 124 and adding a buffer on the backside. The BILD 158 may include insulating materials used to electrically isolate different layers of interconnects and transistors. Common materials include silicon dioxide (SiO₂), low-k dielectrics with lower dielectric constants, organosilicate glass (OSG), porous low-k dielectrics, and hybrid dielectrics. These materials serve to reduce signal delay, capacitance, and improve the overall performance of the semiconductor structure 100, with the choice depending on the specific technology and manufacturing requirements. The BILD 158 may then be etched with a contact opening 160.

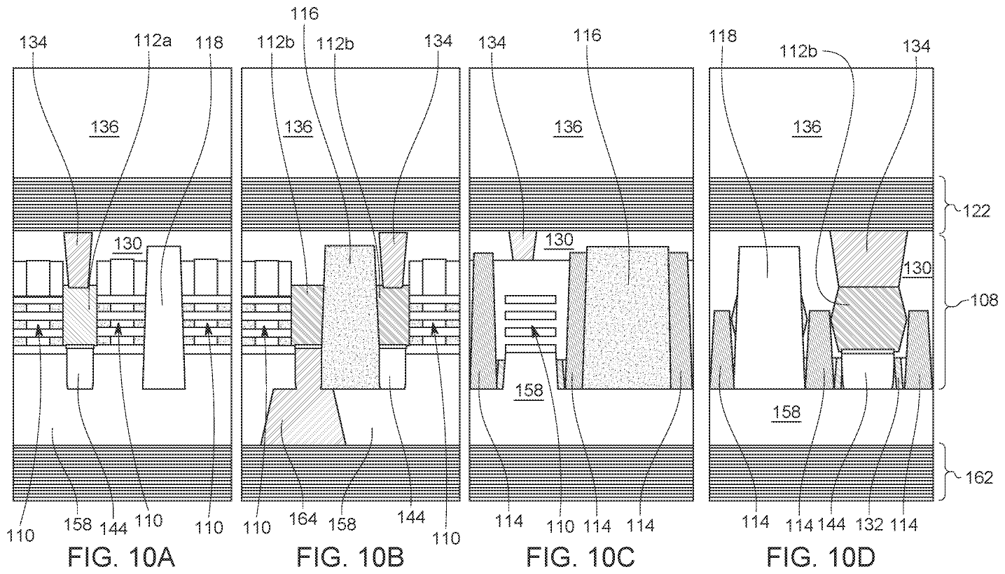

FIGS. 10A-10D depict cross-sectional side views of the semiconductor structure 100 of FIG. 1, with like reference numerals referring to like features at a fabrication stage of the processing method, in accordance with one embodiment of the present invention. The semiconductor structure 100 includes a backside power delivery network (BSPDN) 162 and a backside S/D contact 164 electrically connected between the BSPDN 162 and one of the NFET S/Ds 112b. The BSPDN 162 routes power supply lines on the backside of the semiconductor structure 100 instead of the traditional frontside. This approach increases logic density and improves power and performance by reducing the interconnect resistance and congestion. The BSPDN 162 may be bonded to the semiconductor structure 100, or may be built up directly on the backside of the semiconductor structure 100 one layer at a time.

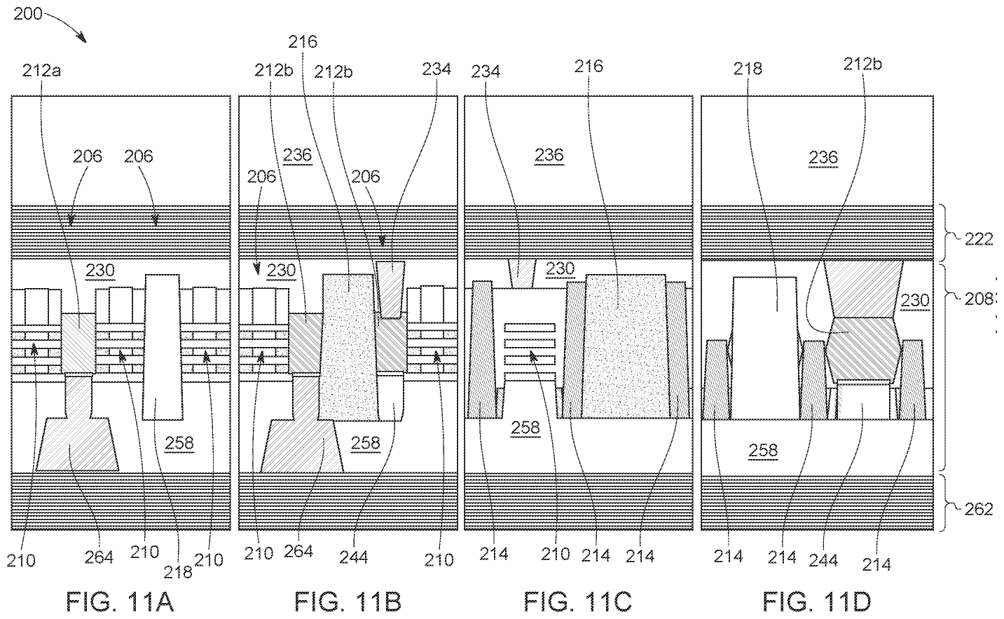

FIGS. 11A-11D depict cross-sectional side views of a semiconductor structure 200 in a similar orientation of rows and columns to the depiction in FIG. 1, in accordance with one embodiment of the present invention. The cross-sectional side views are along the same lines from FIG. 1 as FIGS. 2A-10D. The semiconductor structure 200 includes a FEOL 208 between a BEOL 222 and a BSPDN 262, and further supported by a carrier wafer 236. The FEOL 208 includes FET devices 206 made up of gates 210 and S/Ds 212a, b electrically connected to the BEOL 222 and the BSPDN 262 by contacts 234 and backside contacts 264. In the semiconductor structure 100 above, a NFET S/D 112b is connected to the BSPDN 162 while an adjacent PFET S/D 112a is connected to the BEOL 122. In the semiconductor structure 200 of FIGS. 11A-11D, the PFET S/D 212a and NFET S/D 212b are both connected through the backside to the BSPDN 262. The gates 210 and S/Ds 212a, b are supported by ILD 230 and BILD 258, and are separated into rows along the x-axis by backside gate-and-S/D cut dielectrics (backside cut dielectrics) 214.

The FET devices 206 are further separated by a backside single diffusion break (BSDB) 216 and a backside double diffusion break (BDDB) 218. The BSDB 216 and the BDDB 218 are both formed from the backside, which is discernible by the taper of each from the BSPDN 262 to the BEOL 222. A taper from the BSPDN 262 to the BEOL 222 means that a critical dimension of the BSDB 216 or the BDDB 218 is larger toward the BSPDN 262 and smaller toward the BEOL 222. The BSDB 216 and the BDDB 218 may be fabricated using self-aligned techniques as described above with respect to the semiconductor structure 100. Benefits of such self-aligning include the ability to fabricate the breaks 216, 218 on adjacent rows (i.e., adjacent rows or columns). The self-aligning of the BSDB 216 also results in a structure in which an NFET S/D 212b is directly adjacent to the BSDB 216 and a placeholder 244 is directly beneath the NFET S/D 212b. The semiconductor structure 200 may also include a second NFET S/D 212b directly adjacent to the BSDB on an opposite side of the first NFET S/D 212b with one of the backside S/D contact 264 electrically connected between the second NFET S/D 212b and the BSPDN 262 as illustrated in particular in FIG. 11B. FIG. 11D also illustrates that the BDDB 218 is separated from the placeholder 244 (i.e., the placeholder 244 adjacent to the BSDB 216) by one of the backside cut dielectrics 214.

The methods as described above are used in the fabrication of integrated circuit chips. The resulting integrated circuit chips can be distributed by the fabricator in raw wafer form (e.g., as a single wafer that has multiple unpackaged chips), as a bare die, or in a packaged form. In the latter case, the chip is mounted in a single chip package (e.g., a plastic carrier, with leads that are affixed to a motherboard or other higher level carrier) or in a multichip package (e.g., a ceramic carrier that has either or both surface interconnections or buried interconnections). In any case, the chip may be integrated with other chips, discrete circuit elements, and/or other signal processing devices as part of either an intermediate product or an end product.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A semiconductor structure, comprising:
a back-end-of-line (BEOL) on a first side of a front-end-of-line (FEOL);
a backside power delivery network (BSPDN) on a second side of the FEOL;
a backside single diffusion break (BSDB) tapered from the BSPDN to the BEOL; and
a backside double diffusion break (BDDB) tapered from the BSPDN to the BEOL.

2. The semiconductor structure of claim 1, wherein the BSDB is located on a first row and the BDDB is located on second row adjacent to the first device line.

3. The semiconductor structure of claim 2, wherein the first row comprises an NFET semiconductor and the second row comprises a PFET semiconductor.

4. The semiconductor structure of claim 1, further comprising:
a first source/drain (S/D) directly adjacent to the BSDB; and
a placeholder directly beneath the first S/D.

5. The semiconductor structure of claim 4, further comprising:
a second S/D directly adjacent to the BSDB on an opposite side of the first S/D; and
a backside S/D contact electrically connected between the second S/D and the BSPDN.

6. The semiconductor structure of claim 5, wherein the BSDB is directly between the placeholder and the backside S/D contact.

7. The semiconductor structure of claim 4, further comprising a backside gate-and-S/D cut dielectric between the placeholder and the BDDB.

8. A method of fabricating a semiconductor structure, comprising:
forming a back-end-of-line (BEOL) on a first side of a front-end-of-line (FEOL);
forming a backside single diffusion break (BSDB) tapered toward the BEOL;
forming a backside double diffusion break (BDDB) tapered toward the BEOL; and
forming a backside power delivery network (BSPDN) on a second side of the FEOL.

9. The method of claim 8, wherein forming the BSDB comprises etching a BSDB cut that is self-aligned between a first placeholder and a second placeholder.

10. The method of claim 9, further comprising replacing the first placeholder with a backside S/D contact.

11. The method of claim 9, further comprising forming the first placeholder by replacing a first bottom placeholder.

12. The method of claim 8, wherein forming the BDDB comprises etching a BDDB cut that is self-aligned between backside gate-and-S/D cut dielectrics.

13. The method of claim 8, wherein forming the BDDB comprises etching through a source/drain.

14. A semiconductor structure, comprising:
a backside single diffusion break (BSDB) located on a first row of a front-end-of-line (FEOL) layer of the semiconductor structure; and
a backside double diffusion break (BDDB) located on a second row of the FEOL layer, wherein the second row is directly adjacent to the first row.

15. The semiconductor structure of claim 14, wherein the BSDB and the BDDB are tapered from a backside of the FEOL to a frontside.

16. The semiconductor structure of claim 14, wherein the first row comprises an NFET semiconductor and the second row comprises a PFET semiconductor.

17. The semiconductor structure of claim 14, further comprising:
a first source/drain (S/D) directly adjacent to the BSDB; and
a placeholder directly beneath the first S/D.

18. The semiconductor structure of claim 17, further comprising:
a second S/D directly adjacent to the BSDB on an opposite side of the first S/D; and
a backside S/D contact electrically connected between the second S/D and a backside power delivery network (BSPDN).

19. The semiconductor structure of claim 18, wherein the BSDB is directly between the placeholder and the backside S/D contact.

20. The semiconductor structure of claim 17, further comprising a backside gate-and-S/D cut dielectric between the placeholder and the BDDB.
